(19) United States
(12) Patent Application Publication
(10) Pub. No.: US 2025/0210927 A1
(43) Pub. Date: Jun. 26, 2025

(54) LASER CHAMBER, GAS LASER APPARATUS, AND METHOD FOR MANUFACTURING ELECTRONIC DEVICES

(71) Applicant: Gigaphoton Inc., Tochigi (JP)

(72) Inventor: Takahiro TATSUMI, Oyama-shi (JP)

(73) Assignee: Gigaphoton Inc., Tochigi (JP)

(21) Appl. No.: 18/936,557

(22) Filed: Nov. 4, 2024

(30) Foreign Application Priority Data
Dec. 22, 2023 (JP) 2023-217277

(51) Int. Cl. H01S 3/038; H01S 3/225

(52) U.S. Cl. CPC H01S 3/0381; H01S 3/0382; H01S 3/0385; H01S 3/0388; H01S 3/225

(57) ABSTRACT

A laser chamber according to an aspect of the present disclosure is a laser chamber including a pair of electrodes disposed so as to face each other in a first direction, the laser chamber being configured such that a laser gas can be introduced into the laser chamber, at least one of the pair of electrodes including a discharge section extending in a second direction perpendicular to the first direction, and a shoulder section disposed so as to surround a side surface of the discharge section, a surface of the discharge section having a discharge surface extending in the second direction and an end surface provided at an end portion of the discharge section in the second direction, the end surface being a portion of a spheroid.

### CROSS-REFERENCE TO RELATED APPLICATIONS

The present application claims the benefit of Japanese Patent Application No. 2023-217277, filed on Dec. 22, 2023, the entire contents of which are hereby incorporated by reference.

### BACKGROUND

### 1. Technical Field

The present disclosure relates to a laser chamber, a gas laser apparatus, and a method for manufacturing electronic devices.

### 2. Related Art

In recent years, a semiconductor exposure apparatus is required to improve the resolution thereof as semiconductor integrated circuits are increasingly miniaturized and highly integrated. To this end, reduction in the wavelength of light emitted from a light source for exposure is underway. For example, a KrF excimer laser apparatus, which outputs laser light having a wavelength of about 248 nm, and an ArF excimer laser apparatus, which outputs laser light having a wavelength of about 193 nm, are used as a gas laser apparatus for exposure.

The light from KrF and ArF excimer laser apparatuses that performs spontaneous oscillation has a wide spectral linewidth ranging from 350 to 400 pm. A projection lens made of a material that transmits ultraviolet light, such as KrF and ArF laser light, therefore produces chromatic aberrations in some cases. As a result, the resolution of the projection lens may decrease. To avoid the decrease in the resolution, the spectral linewidth of the laser light output from the gas laser apparatus needs to be narrow enough to make the chromatic aberrations negligible. To this end, a line narrowing module (LNM) including a line narrowing element (such as etalon or grating) is provided in some cases in a laser resonator of the gas laser apparatus to narrow the spectral linewidth. A gas laser apparatus providing a narrowed spectral linewidth is hereinafter referred to as a narrowed-line gas laser apparatus.

### CITATION LIST

### Patent Literature

[PTL 1] WO2023/127286
[PTL 2] JP-UM-A-59-0145052A
[PTL 3] U.S. Pat. No. 10,074,953

### SUMMARY

A laser chamber according to an aspect of the present disclosure is a laser chamber including a pair of electrodes disposed so as to face each other in a first direction, the laser chamber being configured such that a laser gas can be introduced into the laser chamber, at least one of the pair of electrodes including a discharge section extending in a second direction perpendicular to the first direction, and a shoulder section disposed so as to surround a side surface of the discharge section, a surface of the discharge section having a discharge surface extending in the second direction and an end surface provided at an end portion of the discharge section in the second direction, the end surface being a portion of a spheroid.

A gas laser apparatus according to another aspect of the present disclosure is a gas laser apparatus including: a laser chamber that accommodates a pair of electrodes disposed so as to face each other in a first direction, the laser chamber being configured such that a laser gas can be introduced into the laser chamber; a power supply apparatus connected to the pair of electrodes; and a processor configured to control the power supply apparatus to cause the pair of electrodes to perform discharge, at least one of the pair of electrodes including a discharge section extending in a second direction perpendicular to the first direction, and a shoulder section disposed so as to surround a side surface of the discharge section, a surface of the discharge section having a discharge surface extending in the second direction and an end surface provided at an end portion of the discharge section in the second direction, the end surface being a portion of a spheroid.

A method for manufacturing electronic devices according to another aspect of the present disclosure includes introducing a laser gas into a laser chamber of a gas laser apparatus; generating laser light by using the gas laser apparatus; outputting the laser light to an exposure apparatus; and exposing a photosensitive substrate with the laser light in the exposure apparatus to manufacture electronic devices, the gas laser apparatus including the laser chamber that accommodates a pair of electrodes disposed so as to face each other in a first direction, the laser chamber being configured such that a laser gas can be introduced into the laser chamber, a power supply apparatus connected to the pair of electrodes, and a processor configured to control the power supply apparatus to cause the pair of electrodes to perform discharge, at least one of the pair of electrodes including a discharge section extending in a second direction perpendicular to the first direction, and a shoulder section disposed so as to surround a side surface of the discharge section, a surface of the discharge section having a discharge surface extending in the second direction and an end surface provided at an end portion of the discharge section in the second direction, the end surface being a portion of a spheroid.

### BRIEF DESCRIPTION OF DRAWINGS

Embodiments of the present disclosure will be described below only by way of example with reference to the accompanying drawings.

FIG. 1 is a side view schematically showing the configuration of a gas laser apparatus according to Comparative Example.

FIG. 2 is a cross-sectional view schematically showing the configuration of a laser chamber according to Comparative Example.

FIG. 3 is a cross-sectional view of a cathode electrode according to Comparative Example and viewed in a Z direction.

FIG. 4 is a side view of the cathode electrode according to Comparative Example and viewed in an X direction.

FIG. 5 is a cross-sectional view schematically showing the configuration of a laser chamber according to a first embodiment.

FIG. 6 is a perspective view schematically showing a cathode electrode according to the first embodiment.

FIG. 7 is a plan view schematically showing an end portion of the cathode electrode according to the first embodiment.

FIG. 8 is a cross-sectional view of the cathode electrode taken along the line A-A in FIG. 7.

FIG. 9 is a cross-sectional view of the cathode electrode taken along the line B-B in FIG. 7.

FIG. 10 is a descriptive diagram of a spheroid.

FIG. 11 is a side view of the cathode electrodes according to the first embodiment and Comparative Examples and viewed in the X direction.

FIG. 12 is a cross-sectional view of a cathode electrode according to a second embodiment and viewed in the Z direction.

FIG. 13 is a cross-sectional view of the cathode electrode according to the second embodiment and viewed in the X direction.

FIG. 14 is a side view of a cathode electrode according to a third embodiment and viewed in the Z direction.

FIG. 15 is a side view of the cathode electrode according to the third embodiment and viewed in the X direction.

FIG. 16 is a side view of an anode electrode according to a fourth embodiment and viewed in the Z direction.

FIG. 17 is a side view of the anode electrode according to the fourth embodiment and viewed in the X direction.

FIG. 18 schematically shows an example of the configuration of an exposure apparatus.

### DETAILED DESCRIPTION

<Contents>

### 1. Comparative Example

### 1.1 Configuration

### 1.2 Operation

### 1.3 Problems

### 2. First Embodiment

### 2.1 Configuration

### 2.2 Operation

2.3 Effects and advantages

### 3. Second Embodiment

### 3.1 Configuration

### 3.2 Operation

3.3 Effects and advantages

### 4. Third Embodiment

### 4.1 Configuration

### 4.2 Operation

4.3 Effects and advantages

### 5. Fourth Embodiment

### 5.1 Configuration

### 5.2 Operation

5.3 Effects and advantages
6. Method for manufacturing electronic devices

Embodiments of the present disclosure will be described below in detail with reference to the drawings. The embodiments described below show some examples of the present disclosure and are not intended to limit the contents of the present disclosure. Furthermore, all configurations and operations described in the embodiments are not necessarily essential as configurations and operations in the present disclosure. The same element has the same reference character, and no duplicate description of the same element will be made.

### 1. Comparative Example

Comparative Example of the present disclosure will first be described. Comparative Example of the present disclosure is an aspect that the applicant is aware of as known only by the applicant, and is not a publicly known example that the applicant is self-aware of.

### 1.1 Configuration

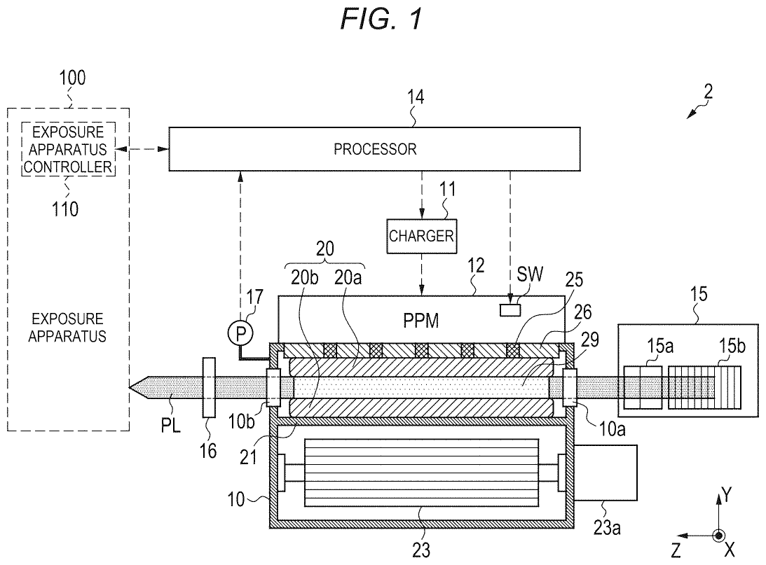

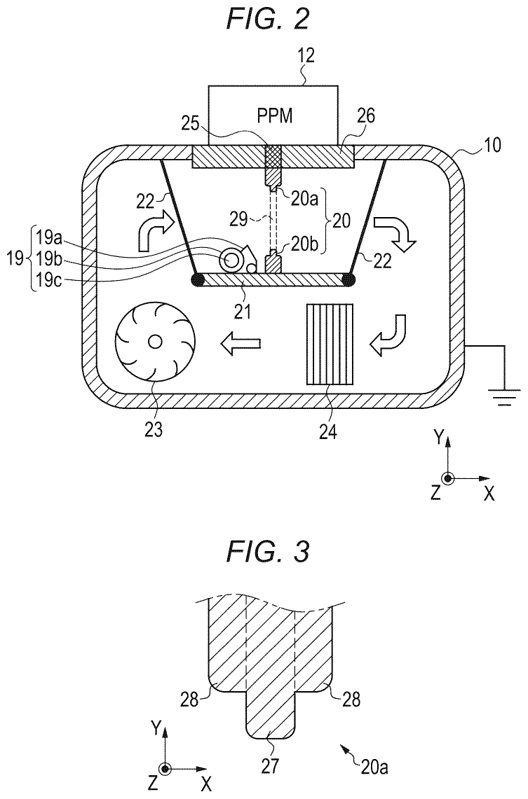

The configuration of a gas laser apparatus 2 according to Comparative Example will be described with reference to FIGS. 1 and 2. FIG. 1 schematically shows the configuration of the gas laser apparatus 2. FIG. 2 is a cross-sectional view of a laser chamber 10 shown in FIG. 1 and viewed in a Z direction. The gas laser apparatus 2 is a discharge-excitation gas laser apparatus that excites a laser gas through discharge, and is, for example, an excimer laser apparatus.

It is assumed in FIG. 1 that the traveling direction of pulse laser light PL output from the gas laser apparatus 2 is the Z direction. The discharge direction, which will be described later, is a Y direction. The Y direction is perpendicular to the Z direction. The direction perpendicular to the Y and Z directions is defined as an X direction. Note that the Y direction corresponds to the “first direction” according to the technology described in the present disclosure. The Z direction corresponds to the “second direction” according to the technology described in the present disclosure. The X direction corresponds to the “third direction” according to the technology described in the present disclosure. The pulse laser light PL is an example of the “laser light” according to the technology described in the present disclosure.

In FIG. 1, the gas laser apparatus 2 includes the laser chamber 10, a charger 11, a pulse power module (PPM) 12, a processor 14, a pressure sensor 17, and a laser resonator. A line narrowing module 15 and an output coupling mirror 16 constitute the laser resonator.

The laser chamber 10 is, for example, a metal container made of aluminum and having a surface plated with nickel. A primary electrode 20, a ground plate 21, wires 22, a fan 23, a heat exchanger 24, and a preliminary ionization electrode 19 are provided inside the laser chamber 10, as shown in FIGS. 1 and 2. The preliminary ionization electrode 19 includes a preliminary ionization outer electrode 19a, a dielectric pipe 19b, and a preliminary ionization inner electrode 19c.

A laser gas containing fluorine has been introduced as a laser medium into the laser chamber 10. The laser gas includes, for example, argon, krypton, xenon, or any other element as a rare gas, neon, helium, or any other element as a buffer gas, and fluorine, chlorine, or any other element as a halogen gas.

The laser chamber 10 further has an opening. An electrically insulating plate 26, in which feedthroughs 25 are embedded, is attached to the laser chamber 10 via an O-ring that is not shown so as to close the opening. The PPM 12 is disposed on the electrically insulating plate 26. The laser chamber 10 is grounded.

The PPM 12 includes a charging capacitor that is not shown and is connected to the primary electrode 20 via the feedthroughs 25. The PPM 12 includes a switch SW, which causes the primary electrode 20 to perform discharge. The charger 11 is connected to the charging capacitor of the PPM 12. The discharge that occurs at the primary electrode 20 is hereinafter referred to as primary discharge. The PPM 12 is an example of the “power supply apparatus” according to the technology described in the present disclosure.

The primary electrode 20 includes a cathode electrode 20a and an anode electrode 20b. The cathode electrode 20a and the anode electrode 20b are disposed so as to face each other in the Y direction. The space between the cathode electrode 20a and the anode electrode 20b is called a discharge space 29. The surface of the cathode electrode 20a that is opposite to the discharge space 29 is supported by the electrically insulating plate 26, and is connected to the feedthroughs 25. The surface of the anode electrode 20b that is opposite to the discharge space 29 is supported by the ground plate 21.

The ground plate 21 is connected to the laser chamber 10 via the wires 22. The laser chamber 10 is grounded. The ground plate 21 is therefore grounded via the wires 22. End portions of the ground plate 21 with regard to the Z direction are fixed to the laser chamber 10.

The fan 23 is a crossflow fan that circulates the laser gas in the laser chamber 10. A motor 23a, which rotationally drives the fan 23, is connected to the laser chamber 10. The heat exchanger 24 exchanges heat between a refrigerant supplied into the heat exchanger 24 and the laser gas.

A laser gas supplier and a laser gas discharger neither of which is shown are connected to the laser chamber 10. The laser gas supplier includes a valve and a flow rate control valve, and is connected to a gas cylinder containing the laser gas. The laser gas discharger includes a valve and a discharge pump.

Windows 10a and 10b are provided at end portions of the laser chamber 10 to cause light generated in the laser chamber 10 to exit out thereof. The laser chamber 10 is so disposed that the optical path of the optical resonator passes through the discharge space 29 and the windows 10a and 10b.

The line narrowing module 15 includes a prism 15a and a grating 15b. The prism 15a increases the beam width of the light having exited out of the laser chamber 10 via the window 10a, and transmits the light toward the grating 15b.

The grating 15b is disposed in the Littrow arrangement, which causes the angle of incidence of the laser light incident on the grating 15b to be equal to the angle of diffraction of the light diffracted by the grating 15b. The grating 15b is a wavelength selection element that selectively extracts light having a specific wavelength and wavelengths in the vicinity thereof in accordance with the angle of diffraction. The light that returns from the grating 15b to the laser chamber 10 via the prism 15a has a narrowed spectral width.

The output coupling mirror 16 transmits part of the light output from the laser chamber 10 via the window 10b and reflects the other part of the light back into the laser chamber 10. The surfaces of the output coupling mirror 16 are coated with a partially reflective film.

The light output from the laser chamber 10 travels back and forth between the line narrowing module 15 and the output coupling mirror 16 and is amplified whenever passing through the discharge space 29. Part of the amplified light is output as the pulse laser light PL via the output coupling mirror 16.

The pressure sensor 17 detects the gas pressure in the laser chamber 10 and outputs the detected value to the processor 14. The processor 14 determines the gas pressure of the laser gas in the laser chamber 10 based on the detected value of the gas pressure and the charging voltage applied by the charger 11.

The charger 11 is a high voltage power supply that supplies the charging voltage to the charging capacitor incorporated in the PPM 12. The switch SW in the PPM 12 is controlled by the processor 14. When the switch SW is turned on from the state in which the switch SW is off, the PPM 12 generates high voltage pulses from the electrical energy stored in the charging capacitor and applies the pulses to the primary electrode 20.

The processor 14 is a processing apparatus that transmits and receives a variety of signals to and from an exposure apparatus controller 110 provided in an exposure apparatus 100. For example, the processor 14 includes a storage apparatus that stores a control program and a CPU (central processing unit) or any other computing apparatus that executes the control program. For example, the processor 14 harmoniously controls the operation of each element of the gas laser apparatus 2 based on the variety of signals transmitted from the exposure apparatus controller 110, the detected value of the gas pressure, and other pieces of information.

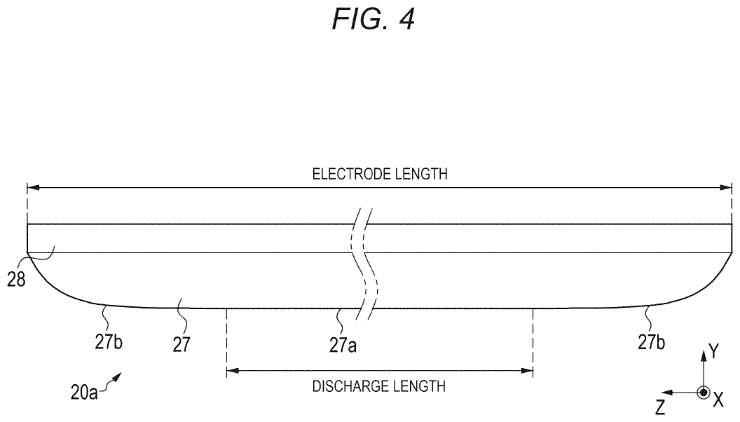

The configuration of the cathode electrode 20a according to Comparative Example will be described with reference to FIGS. 3 and 4. FIG. 3 is a cross-sectional view of the cathode electrode 20a according to Comparative Example and viewed in the Z direction. FIG. 4 is a side view of the cathode electrode 20a according to Comparative Example and viewed in the X direction.

The cathode electrode 20a includes a discharge section 27 and a shoulder section 28, as shown in FIG. 3. For example, the discharge section 27 and the shoulder section 28 are made of a single material, such as brass or copper alloy, and molded into an integral unit. The discharge section 27 protrudes from the shoulder section 28 in the direction toward the anode electrode 20b. The shoulder section 28 is connected to the side surface of the discharge section 27.

The discharge section 27 extends in the Z direction, and has a surface including a discharge surface 27a and end surfaces 27b, as shown in FIG. 4. The discharge surface 27a extends in the Z direction. The end surfaces 27b are provided at end portions of the discharge section 27 in the Z direction. When viewed in the X direction, the discharge surface 27a is a linear surface, and the end surfaces 27b are curved surfaces. The curve that constitutes each of the end surfaces 27b is a smooth curve for suppressing electric field concentration, and is derived, for example, from a theoretical expression established by Ernst et al.

The configuration of the anode electrode 20b is the same as that of the cathode electrode 20a. Specifically, the anode electrode 20b and the cathode electrode 20a have shapes symmetrical with respect to the XZ plane. The length of each of the electrodes in the Z direction will be hereinafter referred to as an “electrode length”. The length of the discharge surface 27a of each of the electrodes in the Z direction will be referred to as a “discharge length”

### 1.2 Operation

The operation of the gas laser apparatus 2 according to Comparative Example will next be described. The processor 14 first drives the motor 23a to rotate the fan 23. The laser gas thus circulates in the laser chamber 10 in the following order: the fan 23; the discharge space 29; and the heat exchanger 24. At this point of time, the shoulder section 28 rectifies the flow of the laser gas to suppress loss in flow speed.

The processor 14 receives an oscillation trigger signal transmitted from the exposure apparatus controller 110. Note that the oscillation trigger signal is a signal that instructs the gas laser apparatus 2 to output the pulse laser light PL corresponding to one pulse. The energy of the pulse laser light PL corresponding to one pulse is referred to as “pulse energy”.

The processor 14 sets a predetermined charging voltage in the charger 11 and operates the switch SW in the PPM 12 in synchronization with the oscillation trigger signal.

When the switch SW in the PPM 12 is turned on from the state in which the switch SW is off, a voltage is applied to the space between the preliminary ionization inner electrode 19c and the preliminary ionization outer electrode 19a of the preliminary ionization electrode 19, and a voltage is applied to the space between the cathode electrode 20a and the anode electrode 20b. As a result, corona discharge occurs at the preliminary ionization electrode 19, and UV (ultraviolet) light is generated. Irradiating the laser gas in the discharge space 29 with the UV light preliminary ionizes the laser gas.

Thereafter, when the voltage between the cathode electrode 20a and the anode electrode 20b reaches the dielectric breakdown voltage, the primary discharge occurs in the discharge space 29. When the discharge direction of the primary discharge is the direction in which the electrons flow, the discharge direction is the direction from the cathode electrode 20a toward the anode electrode 20b. When the primary discharge occurs, the laser gas in the discharge space 29 is excited and emits light.

As the laser gas circulates in the laser chamber 10, discharge products produced in the discharge space 29 move downstream, and a fresh laser gas is supplied to the discharge space 29 during the next discharge. When the laser gas passes through the heat exchanger 24, the heat generated in association with the discharge is removed, so that an increase in the temperature of the laser gas is suppressed.

The light emitted from the laser gas is reflected off the line narrowing module 15 and the output coupling mirror 16 and travels back and forth in the laser resonator, so that laser oscillation occurs. The light having a bandwidth narrowed by the line narrowing module 15 is output as the pulse laser light PL via the output coupling mirror 16. The pulse laser light PL output via the output coupling mirror 16 enters the exposure apparatus 100.

Note that the gas laser apparatus 2 is not necessarily limited to a narrowed-line laser apparatus, and may instead be a laser apparatus that outputs spontaneously oscillating light. For example, the line narrowing module 15 may be replaced with a highly reflective mirror.

Further, in FIGS. 1 and 2, an excimer laser apparatus is shown as the gas laser apparatus 2 by way of example, and the gas laser apparatus 2 may instead, for example, be an F₂ laser apparatus using a laser gas containing a fluorine gas and a buffer gas.

### 1.3 Problems

In the gas laser apparatus 2, to achieve required pulse energy, it is necessary to appropriately set input energy density that is input energy per unit volume in the discharge space 29. To appropriately set the input energy density, it is necessary to appropriately set the volume of the discharge space 29 calculated from the distance between the cathode electrode 20a and the anode electrode 20b, the discharge width, and the discharge length.

It is further required for the gas laser apparatus 2 to output the pulse laser light PL having large pulse energy. To achieve such large pulse energy, it is necessary to increase the input energy while keeping the input energy density appropriately set. To this end, it is conceivable to increase the discharge length.

However, since the cathode electrode 20a and the anode electrode 20b each have the end surfaces 27b, which contribute to the discharge only by a small degree, as shown in FIG. 4, increasing the discharge length to increase the pulse energy greatly increases the electrode length. When the electrode length is increased as described above, it is necessary to lengthen the laser chamber 10, but increasing the length thereof requires a large amount of cost, which is an obstacle to the increase in the pulse energy.

Furthermore, depending on the structure of the laser chamber 10, the end surfaces 27b may disturb the distribution of the flow of the laser gas, resulting in a decrease in the flow speed of the laser gas in some cases.

It is therefore required to realize large pulse energy while suppressing an increase in the length of the laser chamber 10 and a decrease in the flow speed of the laser gas.

### 2. First Embodiment

### 2.1 Configuration

The gas laser apparatus 2 according to a first embodiment of the present disclosure is configured in the same manner as the gas laser apparatus 2 according to Comparative Example except a different configuration in the laser chamber 10.

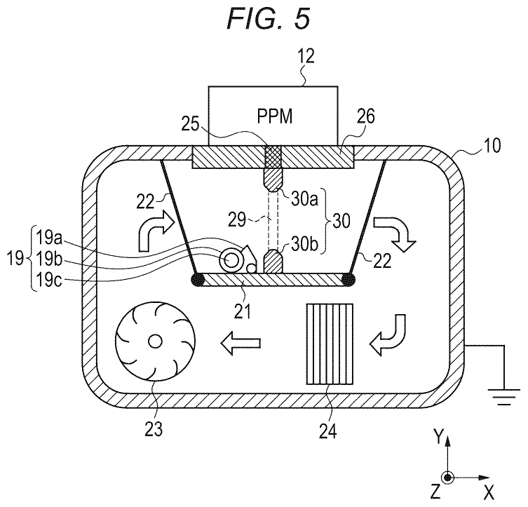

FIG. 5 is a cross-sectional view of a laser chamber 10 according to the first embodiment and viewed in the Z direction. The laser chamber 10 according to the present embodiment differs from the laser chamber 10 according to Comparative Example only in that the primary electrode 20 according to Comparative Example is replaced with a primary electrode 30.

The primary electrode 30 includes a cathode electrode 30a and an anode electrode 30b. The cathode electrode 30a and the anode electrode 30b are the same as the cathode electrode 20a and the anode electrode 20b according to Comparative Example except that the cathode electrode 30a and the anode electrode 30b have shapes different from those of the cathode electrode 20a and the anode electrode 20b. Note that the cathode electrode 30a and the anode electrode 30b are an example of the “pair of electrodes” according to the technology described in the present disclosure.

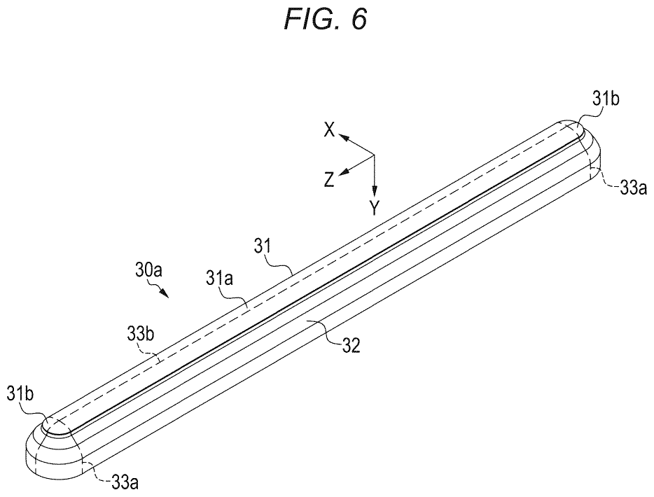

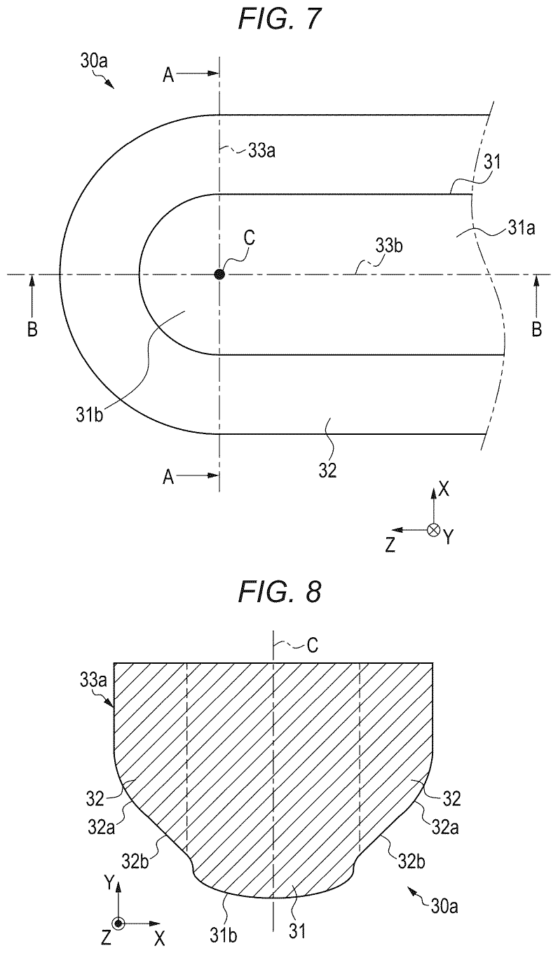

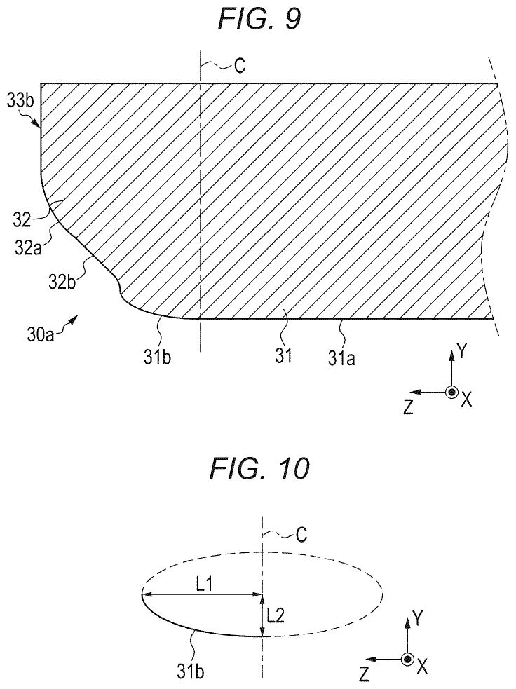

FIGS. 6 to 9 show the configuration of the cathode electrode 30a according to the first embodiment. FIG. 6 is a perspective view schematically showing the cathode electrode 30a. FIG. 7 is a plan view schematically showing an end portion of the cathode electrode 30a. FIG. 8 is a cross-sectional view of the cathode electrode taken along the line A-A in FIG. 7. FIG. 9 is a cross-sectional view of the cathode electrode taken along the line B-B in FIG. 7.

The cathode electrode 30a extends in the Z direction, as shown in FIG. 6. The cathode electrode 30a includes a discharge section 31 and a shoulder section 32. In the present embodiment, the discharge section 31 and the shoulder section 32 are made of a single material, such as brass or copper alloy, and molded into an integral unit. The discharge section 31 protrudes from the shoulder section 32 in the direction toward the anode electrode 30b. The shoulder section 32 is provided so as to surround the side surface of the discharge section 31. The shoulder section 32 rectifies the flow of the laser gas to suppress loss in flow speed.

Note that the discharge section 31 and the shoulder section 32 may be constituted by different parts. In this case, the discharge section 31 and the shoulder section 32 may be made of the same material or different materials.

The discharge section 31 extends in the Z direction, and has a surface including a discharge surface 31a and end surfaces 31b, as shown in FIGS. 6 to 9. The discharge surface 31a extends in the Z direction. The end surfaces 31b are provided at end portions of the discharge section 31 in the Z direction. Specifically, the end surfaces 31b are provided at the opposite end portions of the discharge section 31. The shapes of the two end surfaces 31b are symmetrical with respect to an XY plane, and only one of the end surfaces 31b will therefore be described below.

In the present embodiment, the end surface 31b is a portion of a spheroid around an axis of rotation C. The axis of rotation C is a line where a first cross section 33a, which is a plane of an end portion of the discharge section 31 taken along an XY plane, intersects with a second cross section 33b, which is a plane of the discharge section 31 taken along a YZ plane passing through the center thereof in the X direction. That is, the axis of rotation Cis located at the end of the discharge surface 31a and at the center in the width direction. The XY plane is an example of the “plane parallel to the first and third directions” according to the technology described in the present disclosure. The YZ plane is an example of the “plane parallel to the first and second directions” according to the technology described in the present disclosure.

The end surface 31b is a portion of an oblate spheroid that is the spheroid around the axis of rotation C, which is the minor axis of the spheroid. Let L1 be the major-axis radius of the spheroid that constitutes the end surface 31b thereof, and L2 be the minor-axis radius, as shown in FIG. 10, and it is preferable that the relationship 2≤L1/L2≤10 is satisfied. It is particularly preferable that L1/L2=5.

Furthermore, for example, the end surface 31b is one of four divided surfaces formed by cutting the spheroid with the XY plane containing the minor axis and the XZ plane containing the major axis. The planar shape of the end surface 31b viewed in the Y direction is therefore a semicircular shape, as shown in FIG. 7.

In the end portion of the discharge section 31, the discharge section 31 and the shoulder section 32 are symmetrical with respect to the second cross section 33b. The end portion of the first cross section 33a shown in FIG. 8 and the end portion of the second cross section 33b shown in FIG. 9 therefore have the same cross-sectional shape. The cross-sectional shape used herein is the shape of the discharge section 31 and the shoulder section 32 separated by the axis of rotation C in FIGS. 8 and 9. The term “same cross-sectional shape” includes shapes that are symmetrical with respect to a line and coincides with each other through the reversal operation.

In each of the first cross section 33a and the second cross section 33b, the surface of the shoulder section 32 includes a curved section 32a. The curved section 32a is connected to the end surface 31b via a straight section 32b. The curved section 32a is a portion of a spherical surface around one point on the axis of rotation C. For example, the curved section 32a is a portion of a spherical surface having a radius of 10. The straight section 32b constitutes a tapered surface.

The cross-sectional shape of the discharge surface 31a taken along the width direction at any position and the cross-sectional shape of the end surface 31b of the first cross section 33a have the same elliptical arc.

The configuration of the anode electrode 30b is the same as that of the cathode electrode 30a. Specifically, the anode electrode 30b and the cathode electrode 30a have shapes symmetrical with respect to an XZ plane.

### 2.2 Operation

The operation of the gas laser apparatus 2 according to the present embodiment is the same as that in Comparative Example except that the effects provided by the primary electrode 30 differ from those provided by the primary electrode 20.

### 2.3 Effects and Advantages

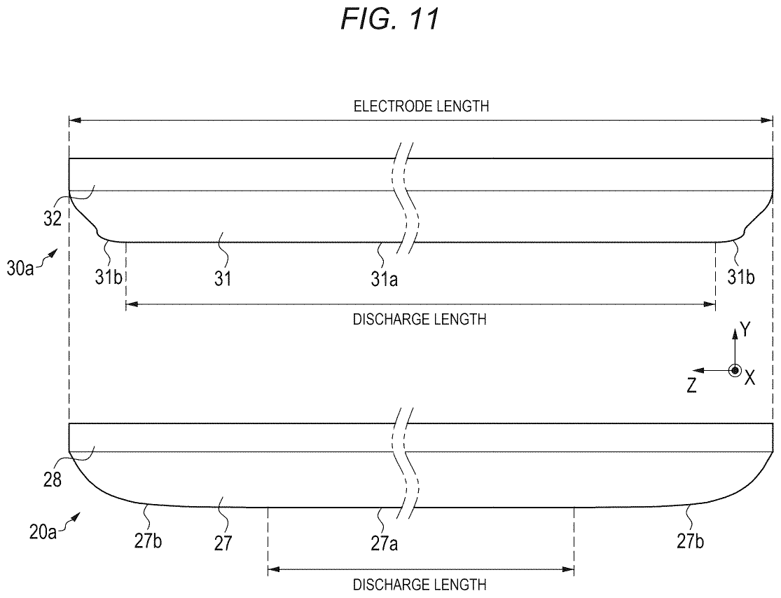

FIG. 11 is a side view of the cathode electrode 30a according to the first embodiment and viewed in the X direction. FIG. 11 shows the cathode electrode 20a according to Comparative Example for comparison.

In the cathode electrode 30a and the anode electrode 30b according to the present embodiment, the end surfaces 31b each have a short length in the Z direction because the end surface 31b is a portion of the spheroid, so that the discharge length can be increased without increasing the electrode length. Large pulse energy can thus be achieved without an increase in the length of the laser chamber 10.

Furthermore, in the present embodiment, the shoulder section 32 is provided also at the end of each of the cathode electrode 30a and the anode electrode 30b in the Z direction, and can rectify the flow of the laser gas at the end as well, so that loss in flow speed can be suppressed.

The present embodiment can therefore achieve large pulse energy while suppressing an increase in the length of the laser chamber 10 and a decrease in the flow speed of the laser gas.

Note that it is preferable that the cathode electrode 30a and the anode electrode 30b have the same configuration as in the embodiment described above, but that only one of the cathode electrode 30a and the anode electrode 30b may have the configuration described in the embodiment described above. For example, the cathode electrode 30a may have the configuration described in the aforementioned embodiment, and the anode electrode 30b may be configured in the same manner as the anode electrode 20b according to Comparative Example.

### 3. Second Embodiment

### 3.1 Configuration

A gas laser apparatus 2 according to a second embodiment of the present disclosure will be described. Note that the same components as those described above have the same reference characters, and duplicate description of the same components will be omitted unless otherwise particularly descried. The gas laser apparatus 2 according to the present embodiment is configured in the same manner as the gas laser apparatus 2 according to the first embodiment except that the cathode electrode 30a and the anode electrode 30b are partially configured differently.

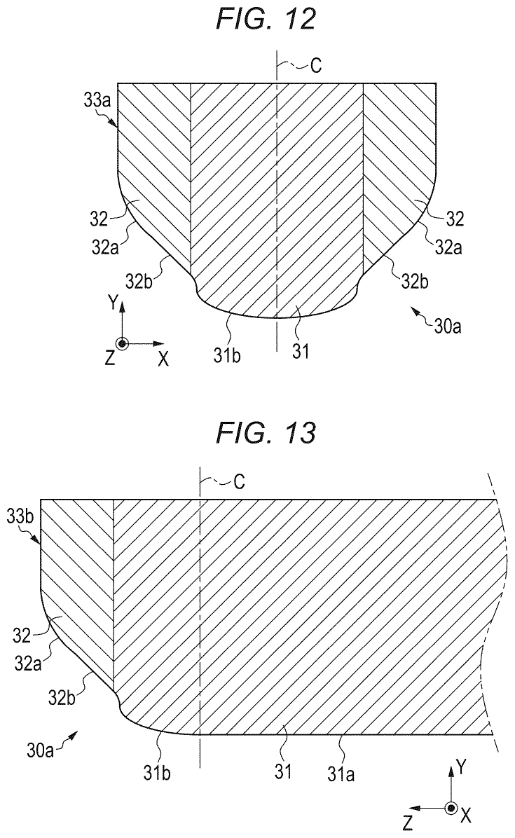

FIGS. 12 and 13 show the configuration of the cathode electrode 30a according to the second embodiment. FIG. 12 is a cross-sectional view of the cathode electrode 30a viewed in the Z direction. FIG. 13 is a cross-sectional view of the cathode electrode 30a viewed in the X direction.

The discharge section 31 and the shoulder section 32 are constituted by different parts in the present embodiment. In the present embodiment, the discharge section 31 is made of a metal material, such as brass and a copper alloy, and the shoulder section 32 is made of an insulating material. For example, the shoulder section 32 is made of a ceramic material, such as alumina and zirconium oxide.

The other configurations of the cathode electrode 30a according to the present embodiment are the same as the configurations of the cathode electrode 30a according to the first embodiment. The configuration of the anode electrode 30b is the same as that of the cathode electrode 30a. The configuration of the anode electrode 30b according to the present embodiment may be the same as the configuration of the anode electrode 20b according to Comparative Example or the anode electrode 30b according to the first embodiment.

### 3.2 Operation

The operation of the gas laser apparatus 2 according to the present embodiment is the same as that in Comparative Example except that the effects provided by the primary electrode 30 differ from those provided by the primary electrode 20.

### 3.3 Effects and Advantages

In the present embodiment, since the shoulder section 32 made of an insulating material surrounds the side surface of the discharge section 31, unexpected discharge other than the discharge at the discharge section 31 can be suppressed in addition to the effects provided by the first embodiment.

### 4. Third Embodiment

### 4.1 Configuration

A gas laser apparatus 2 according to a third embodiment of the present disclosure will be described. Note that the same components as those described above have the same reference characters, and duplicate description of the same components will be omitted unless otherwise particularly descried. The gas laser apparatus 2 according to the present embodiment is configured in the same manner as the gas laser apparatus 2 according to the first embodiment except that the cathode electrode 30a and the anode electrode 30b are partially configured differently.

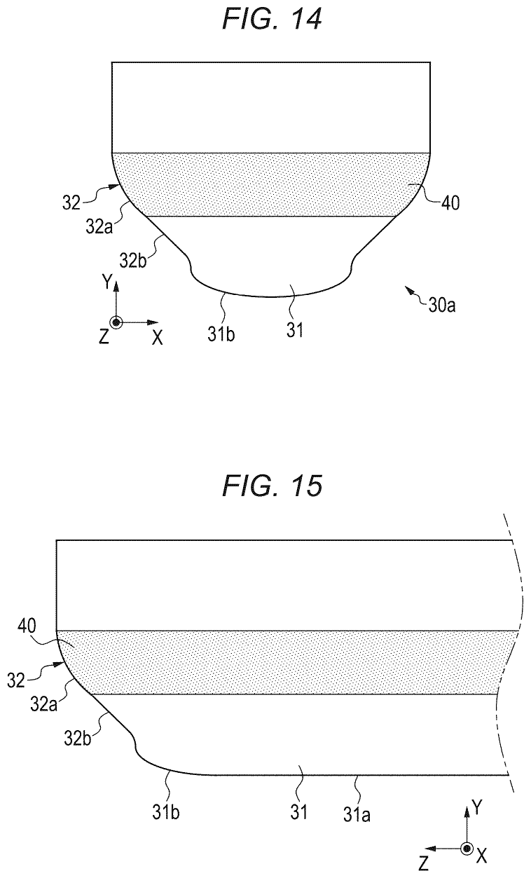

FIGS. 14 and 15 show the configuration of the cathode electrode 30a according to the third embodiment. FIG. 14 is a side view of the cathode electrode 30a viewed in the Z direction. FIG. 15 is a side view of the cathode electrode 30a viewed in the X direction.

In the present embodiment, an insulating film 40 is formed at the surface of the shoulder section 32 of the cathode electrode 30a. For example, the insulating film 40 is formed to cover the curved section 32a. For example, the insulating film 40 is an alumina thermally sprayed coating formed by thermal spray of alumina (Al₂O₃) using plasma thermal spraying. The thickness of the insulating film 40 is preferably 200 μm or smaller.

The other configurations of the cathode electrode 30a according to the present embodiment are the same as the configurations of the cathode electrode 30a according to the first embodiment. The configuration of the anode electrode 30b is the same as that of the cathode electrode 30a. The configuration of the anode electrode 30b according to the present embodiment may be the same as the configuration of the anode electrode 20b according to Comparative Example or the anode electrode 30b according to the first or second embodiment.

### 4.2 Operation

The operation of the gas laser apparatus 2 according to the present embodiment is the same as that in Comparative Example except that the effects provided by the primary electrode 30 differ from those provided by the primary electrode 20.

### 4.3 Effects and Advantages

In the present embodiment, since the insulating film 40 is formed at the surface of the shoulder section 32, unexpected discharge other than the discharge at the discharge section 31 can be suppressed in addition to the effects provided by the first embodiment.

### 5. Fourth Embodiment

### 5.1 Configuration

A gas laser apparatus 2 according to a fourth embodiment of the present disclosure will be described. Note that the same components as those described above have the same reference characters, and duplicate description of the same components will be omitted unless otherwise particularly descried. The gas laser apparatus 2 according to the present embodiment is configured in the same manner as the gas laser apparatus 2 according to the first embodiment except that the anode electrode 30b is partially configured differently.

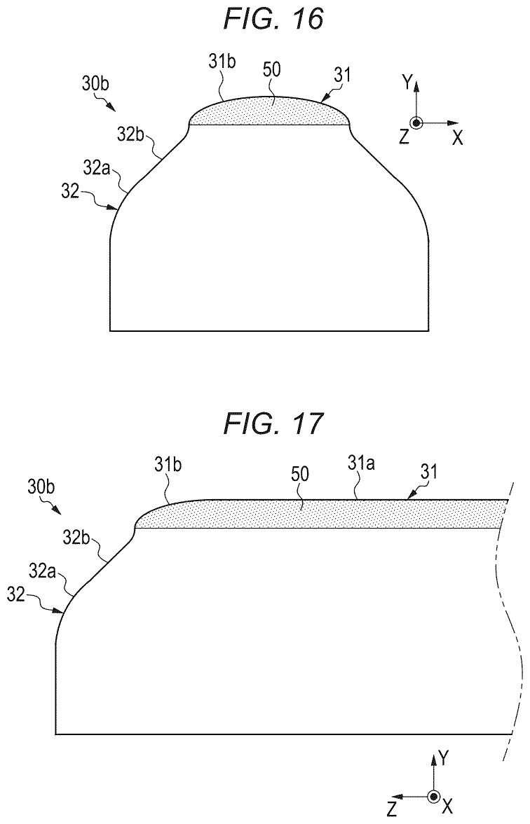

FIGS. 16 and 17 show the configuration of the anode electrode 30b according to the fourth embodiment. FIG. 16 is a side view of the anode electrode 30b viewed in the Z direction. FIG. 17 is a side view of the anode electrode 30b viewed in the X direction.

The anode electrode 30b is configured in the same manner as the cathode electrode 30a, and includes a discharge section 31 extending in the Z direction and a shoulder section 32 provided so as to surround the side surface of the discharge section 31. The surface of the discharge section 31 has a discharge surface 31a extending in the Z direction and end surfaces 31b provided at both end portions of the discharge section 31 in the direction in which the discharge section 31 extends. The end surfaces 31b are each a portion of a spheroid. The other configurations of the anode electrode 30b according to the present embodiment are same as the configurations of the cathode electrode 30a according to any of the first to third embodiments except that an orientation of the anode electrode 30b is different from that of the cathode electrode 30a.

In the present embodiment, an alumina thermally sprayed coating 50, in which metal such as copper is dispersed, is formed at each of the discharge surface 31a and the end surfaces 31b of the anode electrode 30b. The alumina thermally sprayed coating 50 is formed by plasma thermal spraying. The thickness of the alumina thermally sprayed coating 50 is preferably 200 μm or smaller.

The cathode electrode 30a according to the present embodiment is configured in the same as the cathode electrode 30a according to any of the first to third embodiments.

### 5.2 Operation

The operation of the gas laser apparatus 2 according to the present embodiment is the same as that in Comparative Example except that the effects provided by the primary electrode 30 differ from those provided by the primary electrode 20.

### 5.3 Effects and Advantages

In the present embodiment, since the alumina thermally sprayed coating 50 is formed at each of the discharge surface 31a and the end surfaces 31b of the anode electrode 30b, the effect of suppressing deterioration of the anode electrode 30b due to the impact of the discharge can be provided in addition to the effects provided by any of the first to third embodiments. The life of the primary electrode 30 is thus prolonged. Note that the effect described above is known from Japanese Patent No. 4,059,758 and Japanese Patent No. 4,367,886.

### 6. Method for Manufacturing Electronic Devices

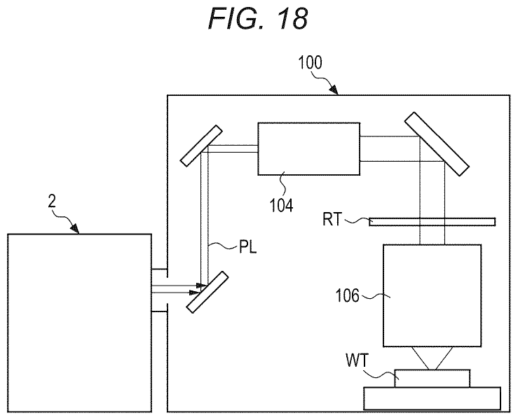

FIG. 18 schematically shows an example of the configuration of the exposure apparatus 100. The exposure apparatus 100 includes an illumination optical system 104 and a projection optical system 106. The illumination optical system 104 illuminates a reticle pattern of a reticle that is not shown but is placed on a reticle stage RT, for example, with the pulse laser light PL having entered the illumination optical system 104 from the gas laser apparatus 2. The projection optical system 106 performs reduction projection on the pulse laser light PL having passed through the reticle to bring the pulse laser light PL into focus at a workpiece that is not shown but is placed on a workpiece table WT. The workpiece is a photosensitive substrate onto which a photoresist has been applied, such as a semiconductor wafer.

The exposure apparatus 100 synchronously moves the reticle stage RT and the workpiece table WT in parallel to expose the workpiece to the pulse laser light PL having reflected the reticle pattern. Semiconductor devices can be manufactured by transferring the reticle pattern onto the semiconductor wafer in the exposure step described above and then carrying out multiple other steps. The semiconductor devices are an example of the “electronic devices” in the present disclosure.

Note that the gas laser apparatus 2 does not necessarily manufacture electronic devices, and can also be used to perform laser processing such as drilling.

The description above is intended to be illustrative and the present disclosure is not limited thereto. Therefore, it would be obvious to those skilled in the art that various modifications to the embodiments of the present disclosure would be possible without departing from the spirit and the scope of the appended claims.

The terms used throughout the present specification and the appended claims should be interpreted as non-limiting terms. For example, terms such as “comprise”, “include”, “have”, and “contain” should not be interpreted to be exclusive of other structural elements. Further, indefinite articles “a/an” described in the present specification and the appended claims should be interpreted to mean “at least one” or “one or more”. Further, “at least one of A, B, and C” should be interpreted to mean any of A, B, C, A+B, A+C, B+C, and A+B+C as well as to include combinations of any thereof and any other than A, B, and C.

What is claimed is:

1. A laser chamber comprising:
a pair of electrodes disposed so as to face each other in a first direction, the laser chamber being configured such that a laser gas can be introduced into the laser chamber,
at least one of the pair of electrodes including a discharge section extending in a second direction perpendicular to the first direction, and a shoulder section disposed so as to surround a side surface of the discharge section,
a surface of the discharge section having a discharge surface extending in the second direction and an end surface provided at an end portion of the discharge section in the second direction,
the end surface being a portion of a spheroid.

2. The laser chamber according to claim 1,
wherein the discharge section protrudes in the first direction from the shoulder section.

3. The laser chamber according to claim 1,
wherein a third direction is defined as a direction perpendicular to the first and second directions, and
an axis of rotation of the spheroid is an intersection of a first cross section of the end portion taken along a plane parallel to the first and third directions and a second cross section of the end portion taken along a plane parallel to the first and second directions.

4. The laser chamber according to claim 3,
wherein the first and second cross sections of the end portion have the same cross-sectional shape.

5. The laser chamber according to claim 4,
wherein the spheroid is an oblate spheroid around a minor axis thereof as the axis of rotation.

6. The laser chamber according to claim 5,
wherein 2≤L1/L2≤10 is satisfied, where L1 represents a radius of the spheroid along a major axis thereof, and L2 represents a radius of the spheroid along the minor axis thereof.

7. The laser chamber according to claim 1,
wherein the discharge section and the shoulder section are made of a single material and molded into an integrated unit.

8. The laser chamber according to claim 1,
wherein the discharge section and the shoulder section are constituted by different parts.

9. The laser chamber according to claim 8,
wherein the shoulder section is made of an insulating material.

10. The laser chamber according to claim 9,
wherein the insulating material is alumina or zirconium oxide.

11. The laser chamber according to claim 1,
wherein an insulating film is formed at a surface of the shoulder section.

12. The laser chamber according to claim 11,
wherein the insulating film is an alumina thermally sprayed coating.

13. The laser chamber according to claim 12,
wherein the insulating film has a thickness of 200 μm or smaller.

14. The laser chamber according to claim 1,
wherein one of the pair of electrodes is an anode electrode having an alumina thermally sprayed coating in which metal is dispersed, the coating formed at each of the discharge surface and the end surface of the electrode.

15. The laser chamber according to claim 14,
wherein the alumina thermally sprayed coating has a thickness of 200 μm or smaller.

16. The laser chamber according to claim 1,
wherein the shoulder section rectifies a flow of the laser gas.

17. A gas laser apparatus comprising:
a laser chamber that accommodates a pair of electrodes disposed so as to face each other in a first direction, the laser chamber being configured such that a laser gas can be introduced into the laser chamber;
a power supply apparatus connected to the pair of electrodes; and
a processor configured to control the power supply apparatus to cause the pair of electrodes to perform discharge,
at least one of the pair of electrodes including a discharge section extending in a second direction perpendicular to the first direction, and a shoulder section disposed so as to surround a side surface of the discharge section,
a surface of the discharge section having a discharge surface extending in the second direction and an end surface provided at an end portion of the discharge section in the second direction,
the end surface being a portion of a spheroid.

18. A method for manufacturing electronic devices, the method comprising:
introducing a laser gas into a laser chamber of a gas laser apparatus;
generating laser light by using the gas laser apparatus;
outputting the laser light to an exposure apparatus; and
exposing a photosensitive substrate with the laser light in the exposure apparatus to manufacture electronic devices,
the gas laser apparatus including
the laser chamber that accommodates a pair of electrodes disposed so as to face each other in a first direction, the laser chamber being configured such that a laser gas can be introduced into the laser chamber,
a power supply apparatus connected to the pair of electrodes, and
a processor configured to control the power supply apparatus to cause the pair of electrodes to perform discharge,
at least one of the pair of electrodes including a discharge section extending in a second direction perpendicular to the first direction, and a shoulder section disposed so as to surround a side surface of the discharge section,
a surface of the discharge section having a discharge surface extending in the second direction and an end surface provided at an end portion of the discharge section in the second direction,
the end surface being a portion of a spheroid.
